(19) United States
(12) Patent Application Publication
(10) Pub. No.: US 2011/0110537 A1
(43) Pub. Date: May 12, 2011

(54) Light-Powered Loudspeaker System

(76) Inventor: Tzu-Chung Chang, NiaoSong Township (TW)

(21) Appl. No.: 12/613,659

(22) Filed: Nov. 6, 2009

(51) Int. Cl. H03F 99/00

(52) U.S. Cl. 381/120

(57) ABSTRACT

A light-powered loudspeaker system including a solar power generator, a power storage device, a wireless signal receiver, a power amplifier and a speaker module is disclosed. The solar power generator is configured to receive a solar energy and convert the received solar energy into electricity energy. The power storage device is coupled to the solar power generator for storing the converted electricity energy. The wireless signal receiver is coupled to the power storage device, receives wireless audio signals and generates an output signal. The power amplifier is coupled to the power storage device and the wireless signal receiver, amplifies the output signal and generates an amplified audio signal. The speaker module is coupled to the power amplifier and produces voices according to the amplified audio signal.

### BACKGROUND OF THE INVENTION

1. Field of the Invention

The present invention relates to a light-powered loudspeaker system.

2. Description of the Related Art

FIG. 1 depicts a diagram of a traditional loudspeaker system. The loudspeaker system 8 comprises a wireless signal receiver 81, a power amplifier 82 and a speaker module 83. The wireless signal receiver 81 and power amplifier 82 are electrically connected to an outlet 9 via power cables 91. With the structure, electricity is provided to the wireless signal receiver 81 and power amplifier 82 in a wired manner, thus limiting the mobility of the loudspeaker system 8.

In a related art, the loudspeaker system 8 is equipped with a built-in battery instead of the power cables 91. This improves the mobility of the loudspeaker system 8. However, it is required to frequently change/recharge the built-in battery to ensure the operation of the loudspeaker system 8, making it more inconvenient to use the loudspeaker system 8. Additionally, the wasted batteries may be harmful to the environment.

In light of the problem, it exists a need for a loudspeaker system that uses a new energy solution, while maintaining the high mobility.

### SUMMARY OF THE INVENTION

The invention discloses a loudspeaker system including a solar power generator, an adjusting element, a power storage device, a wireless signal receiver, a power amplifier and a speaker module. The solar power generator is configured to receive a solar energy and convert the received solar energy into electricity energy. The adjusting element is used to adjust the angle and the direction of a light-receiving surface of the solar power generator with respect to the outer surface of the casing, therefore the solar energy can be efficiently received by the solar power generator. The power storage device is coupled to the solar power generator for storing the converted electricity energy. The wireless signal receiver is coupled to the power storage device, receives wireless audio signals and generates an output signal. The power amplifier is coupled to the power storage device and the wireless signal receiver, amplifies the output signal and generates an amplified audio signal. The speaker module is coupled to the power amplifier and produces voices according to the amplified audio signal.

### BRIEF DESCRIPTION OF THE DRAWINGS

The present invention will become more fully understood from the detailed description given hereinafter and the accompanying drawings which are given by way of illustration only, and thus are not limitative of the present invention, and wherein:

FIG. 1 depicts a diagram of a traditional loudspeaker system;

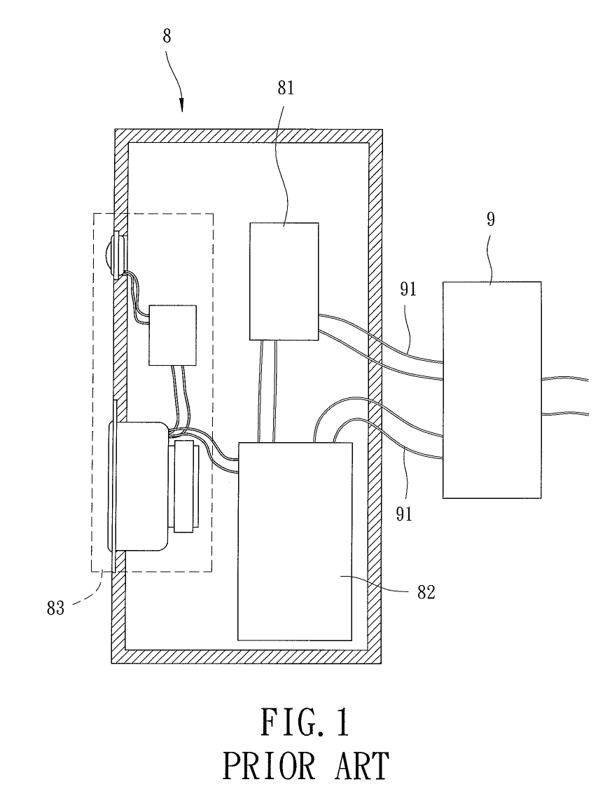

FIG. 2 depicts a diagram of a loudspeaker system according to a preferred embodiment of the invention; and

FIG. 3 depicts a perspective view of the proposed loudspeaker system according to the preferred embodiment of the invention.

In the various figures of the drawings, the same numerals designate the same or similar parts. Furthermore, when the terms “first”, “second” and similar terms are used hereinafter, it should be understood that these terms are reference only to the structure shown in the drawings as it would appear to a person viewing the drawings and are utilized only to facilitate describing the invention.

### DETAILED DESCRIPTION OF THE INVENTION

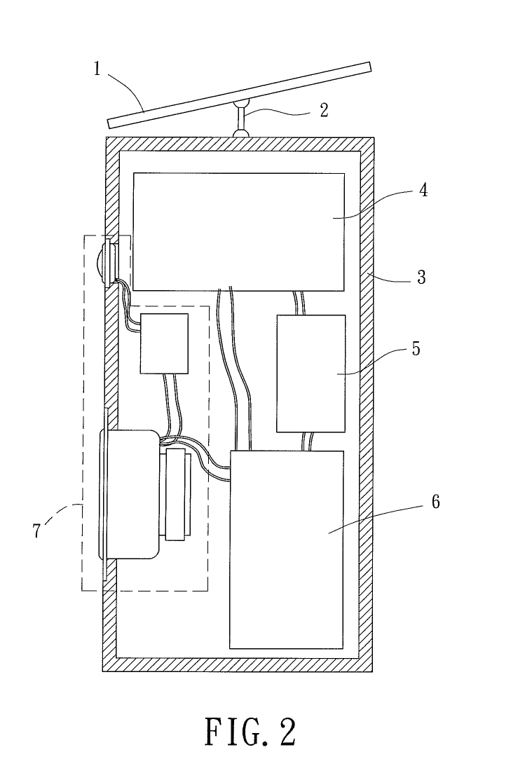

FIG. 2 depicts a diagram of a loudspeaker system according to a preferred embodiment of the invention. The loudspeaker system comprises a solar power generator 1, an adjusting element 2, a casing 3, a power storage device 4, a wireless signal receiver 5, a power amplifier 6 and a speaker module 7.

In the structure of FIG. 2, the solar power generator 1, which preferably includes a solar panel, is configured to receive the solar energy and convert the received solar energy into electricity energy. The solar power generator 1 is coupled to an outer surface of the casing 3 via the adjusting element 2, such that the angle and the direction of a light-receiving surface of the solar power generator 1 with respect to the outer surface of the casing 3 can be adjusted. By properly adjusting the angle of the light-receiving surface of the solar power generator 1, the solar energy is efficiently received by the solar power generator 1. The power storage device 4, wireless signal receiver 5, power amplifier 6 and speaker module 7 may be disposed in the casing 3.

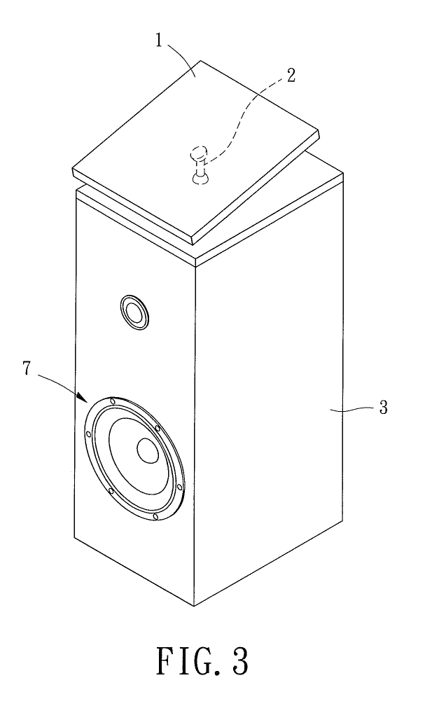

The solar power generator 1 is electrically connected to the power storage device 4 so that the electricity energy converted from the received solar energy is stored therein. The stored electricity is then provided to the related devices to ensure the normal operation of the loudspeaker system. In particular, the power storage device 4 is electrically connected to the wireless signal receiver 5 and the power amplifier 6 so that the required electricity of the wireless signal receiver 5 and the power amplifier 6 is provided. The wireless signal receiver 5 is electrically coupled to a audio signal transmitter (not shown) in a wireless manner in order to receive wireless audio signals therefrom. The wireless signal receiver 5 may be an infrared receiver or a Bluetooth receiver, but is not limited thereto. After receiving the wireless audio signals, the wireless signal receiver 5 performs a series of signal processing on the received audio signals to generate an output signal, such as signal detecting or filtering, but is not limited thereto. In addition, since the wireless signal receiver 5 is electrically connected to the power amplifier 6, the wireless signal receiver 5 sends the output signal to the power amplifier 6. The power amplifier 6 is configured to amplify the output signal to generate an amplified audio signal. Besides, since the power amplifier 6 is electrically connected to the speaker module 7, the amplified audio signal can be sent to the speaker module 7 for producing voices. According to the above-illustrated embodiment of the present invention, an appearance drawing of the proposed loudspeaker system is shown in FIG. 3.

Although the invention has been described in detail with reference to its presently preferable embodiment, it will be understood by one of ordinary skill in the art that various modifications can be made without departing from the spirit and the scope of the invention, as set forth in the appended claims.

What is claimed is:

1. A light-powered loudspeaker system, comprising:
a solar power generator configured to receive a solar energy and convert the received solar energy into electricity energy;
a power storage device coupled to the solar power generator and storing the converted electricity energy;
a wireless signal receiver coupled to the power storage device, receiving wireless audio signals and generating an output signal;
a power amplifier coupled to the power storage device and the wireless signal receiver, amplifying the output signal and generating an amplified audio signal; and
a speaker module coupled to the power amplifier and producing voices according to the amplified audio signal.

2. The light-powered loudspeaker system as claimed in claim 1, further comprising:
a casing for accommodating the power storage device, the wireless signal receiver, the power amplifier and the speaker module; and
an adjusting element for coupling the solar power generator to the casing, thereby allowing the angle and the direction of the solar power generator with respect to the casing to be adjusted.

3. The light-powered loudspeaker system as claimed in claim 1, wherein the wireless signal receiver is an infrared receiver.

4. The light-powered loudspeaker system as claimed in claim 1, wherein the wireless signal receiver is a Bluetooth receiver.

5. The light-powered loudspeaker system as claimed in claim 1, wherein the wireless signal receiver further performs signal detecting and signal filtering on the wireless audio signals to generate the output signal.

6. The light-powered loudspeaker system as claimed in claim 1, wherein the solar power generator is a solar panel.
